(19) United States
(12) Patent Application Publication
(10) Pub. No.: US 2014/0114629 A1
(43) Pub. Date: Apr. 24, 2014

(54) Process Model Transition Visualization

(71) Applicant: Lexmark International, Inc., (US)

(72) Inventors: Georgi Jojgov, Apeldoorn (NL); Peter van den Brand, Apeldoorn (NL)

(73) Assignee: LEXMARK INTERNATIONAL, INC., Lexington, KY (US)

(21) Appl. No.: 13/732,146

(22) Filed: Dec. 31, 2012

Related U.S. Application Data
(60) Provisional application No. 61/647,484, filed on May 15, 2012.

(51) Int. Cl. G06F 17/50; G06Q 10/06

(52) U.S. Cl. CPC G06F 17/50; G06Q 10/067
USPC 703/6

(57) ABSTRACT

A method of visually representing a process that includes creating a case representation for each case in the process, representing the process as a workflow having states and transitions, displaying a progression of each case representation from one state to a next state at a speed representing an amount of time for the each case to reach the next state from the one state; and varying an appearance of the transition depending on a performance metric at a time interval.

### CROSS REFERENCES TO RELATED APPLICATIONS

None.

### STATEMENT REGARDING FEDERALLY SPONSORED RESEARCH OR DEVELOPMENT

None.

### REFERENCE TO SEQUENTIAL LISTING, ETC

None.

### BACKGROUND

1. Field of the Disclosure

The present disclosure relates generally to process modeling, and more particularly, to process model visualization and arc animation.

2. Description of the Related Art

Businesses often record or store raw data or information, such as in a data log, relating to business or workflow processes implemented in a system. This type of data may be highly valuable to a company desiring to better understand the workflows involved in accomplishing a particular process goal by providing insight on how existing processes are being implemented by users of the system. This data may also help a company in determining whether its current processes are operating as intended, identifying bottlenecks or areas which need improvement or affect the efficiency of the process and/or assessing the effect of process changes.

In order to help businesses better understand their business or workflow processes more efficiently, the processes may be automatically modeled using actual raw data. Additional insight on the efficiencies and effectiveness of a process may be gleaned if each case in the process is represented in the process model and even more so if the movement of the cases between each states in the process and the transitions of the cases from one state to the other are visualized. For example, the visualization of the cases may be used to more readily identify which state in the process some cases tend to persist or if there are instances in the process where one or more cases proceed too slow or too fast from one state to another. Visualization of the transitions in the process model may also be used to indicate the volume of cases that moves from one state to another over a period of time. Visualizing the movement of cases in a process may also more readily demonstrate the effects of a modification on a process or validate whether a process is being executed as intended.

Existing solutions may provide some form of visualization of cases and transitions. However, these solutions simply visualize the paths of cases from one state to another through one or more transitions and do not take into account the rate of the movement of the cases through a fixed time in the visualization, nor do these applications vary the appearance of the transitions based on one or more transaction-related data. Known solutions that provide a variation in the appearance of transitions also do not vary the appearance of the transitions relative to each other based on one or more transaction-related data.

Thus, what is needed is a system and method for effectively and efficiently visualizing cases and transitions in at least one process at a specified period of time. It is also desirable for the system and method to illustrate the movement of the cases from one state of the process to another and show the speed at which the cases transition between the states and the number of cases that transition from one state to another. Such system and method for illustrating cases and transitions in a model are needed in order to identify the progression of cases in a process over a period of time and to show deviations from the defined boundaries or expectations that a company or other entity may have for implemented business or workflow processes.

### SUMMARY

A system capable of and methods for visually representing a process are disclosed herein. A case representation may be created corresponding to each case in the process. In one example embodiment, the process may be represented as a workflow having states and transitions. A progression of each case representation may be displayed from one state to a next state at a speed representing an amount of time for each case to reach the next state from the one state and the appearance of the transitions in the workflow may be varied depending upon a performance metric at a time interval.

According to one example embodiment, the time interval may be a time between two frames. In another example embodiment, the time interval may be a fixed time. In one aspect, the fixed time may be based upon an entire time period from which the process that is visualized is based. In another example embodiment, the performance metric may be a number of case representations progressing from the one state to the next state.

### BRIEF DESCRIPTION OF THE DRAWINGS

The above-mentioned and other features and advantages of the present disclosure, and the manner of attaining them, will become more apparent and will be better understood by reference to the following description of example embodiments taken in conjunction with the accompanying drawings. Like reference numerals are used to indicate the same element throughout the specification.

FIG. 1 is one example embodiment for process model visualization.

FIG. 2 is one example process model for use in the process model visualization of FIG. 1.

FIGS. 3A-3D are example frames of a visualization of a process model that visualize a movement of case representations from one state or transition to another and the variation of the appearance of transitions.

FIG. 4 is an example frame in the visualization of a process model with states varying for each frame.

### DETAILED DESCRIPTION

It is to be understood that the disclosure is not limited to the details of construction and the arrangement of components set forth in the following description or illustrated in the drawings. The disclosure is capable of other embodiments and of being practiced or of being carried out in various ways. For example, other embodiments may incorporate structural, chronological, process, and other changes. Examples merely typify possible variations. Individual components and functions are optional unless explicitly required, and the sequence of operations may vary. Portions and features of some embodiments may be included in or substituted for those of others. The scope of the application encompasses the appended claims and all available equivalents. The following description is, therefore, not to be taken in a limited sense, and the scope of the present disclosure is defined by the appended claims.

Also, it is to be understood that the phraseology and terminology used herein is for the purpose of description and should not be regarded as limiting. The use herein of “including,” “comprising,” or “having” and variations thereof is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings. In addition, the terms “connected” and “coupled” and variations thereof are not restricted to physical or mechanical connections or couplings. Further, the terms “a” and “an” herein do not denote a limitation of quantity, but rather denote the presence of at least one of the referenced item.

It will be further understood that each block of the diagrams, and combinations of blocks in the diagrams, respectively, may be implemented by computer program instructions. These computer program instructions may be loaded onto a general purpose computer, special purpose computer, or other programmable data processing apparatus to produce a machine, such that the instructions which execute on the computer or other programmable data processing apparatus may create means for implementing the functionality of each block of the diagrams or combinations of blocks in the diagrams discussed in detail in the descriptions below.

These computer program instructions may also be stored in a non-transitory computer-readable medium that may direct a computer or other programmable data processing apparatus to function in a particular manner, such that the instructions stored in the computer-readable medium may produce an article of manufacture including an instruction means that implements the function specified in the block or blocks. The computer program instructions may also be loaded onto a computer or other programmable data processing apparatus to cause a series of operational steps to be performed on the computer or other programmable apparatus to produce a computer implemented process such that the instructions that execute on the computer or other programmable apparatus implement the functions specified in the block or blocks.

Accordingly, blocks of the diagrams support combinations of means for performing the specified functions, combinations of steps for performing the specified functions and program instruction means for performing the specified functions. It will also be understood that each block of the diagrams, and combinations of blocks in the diagrams, can be implemented by special purpose hardware-based computer systems that perform the specified functions or steps, or combinations of special purpose hardware and computer instructions.

Disclosed are a system and methods for process model visualization that includes creating a case representation for each case in a process, representing the process as a workflow having states and transitions, displaying a progression of each case representation from one state to a next state at a speed representing an amount of time for each case to reach the next state from the one state, and animating or varying an appearance of the arc or transition depending on a number of case representations progressing from the one state to the next state at a set time interval. In some example embodiments, the appearance of the state may be varied depending on a number of case representations in the state during a set time interval. In other example embodiments, both the appearance of the transitions and the states may be varied. In yet other alternative example embodiments, varying the appearance of the transitions and/or the states may depend on other information, as will be discussed in greater detail below.

Process models may be visually represented by a combination of states and transitions that show how a process may be executed in a given system. States may be the events, actions or operations of a process. For example, states may represent steps in a process or workflow. State labels may be identifiers, such as text, that correspond to the states in a process model.

Transitions in a process model may illustrate the direction or movement between an input state and an output state. The input state of a transition may correspond to event, action or operation that leads the input state to the output state. The output state of a transition may correspond to the event, action or operation that occurs after the input state of the transition.

In some example embodiments, process models may be created manually by a user. For example, a user may illustrate a process model by hand or using graphics software. A process model may then be printed or stored electronically for future use. In one aspect, a hard copy of a process model may be scanned by an image-capturing device and translated into a format recognizable by a processor.

In other example embodiments, process models also may be automatically generated from data sets, such as an event log, using conventional or proprietary process mining techniques. As will be understood by those of ordinary skill in the art, process mining is the method for extracting process models from data sets, and conventional process mining techniques include alpha, genetic mining, heuristic and fuzzy miner algorithms.

Data sets may include data entries wherein each entry has a case identifier, time stamp and state information. A case identifier may refer to a recorded indicator, such as a number, that identifies which activities are associated with a particular process instance. For example, a case identifier may uniquely identify the object, subject or item going through a state. Time stamp may refer to a date and/or time at which the state indicated by the case identifier occurred. State information may be a description of the state and may represent, for example, an activity, transaction type, physical location or name identifier.

In yet alternative example embodiments, process models may be generated by a combination of manual techniques and automatic process mining techniques.

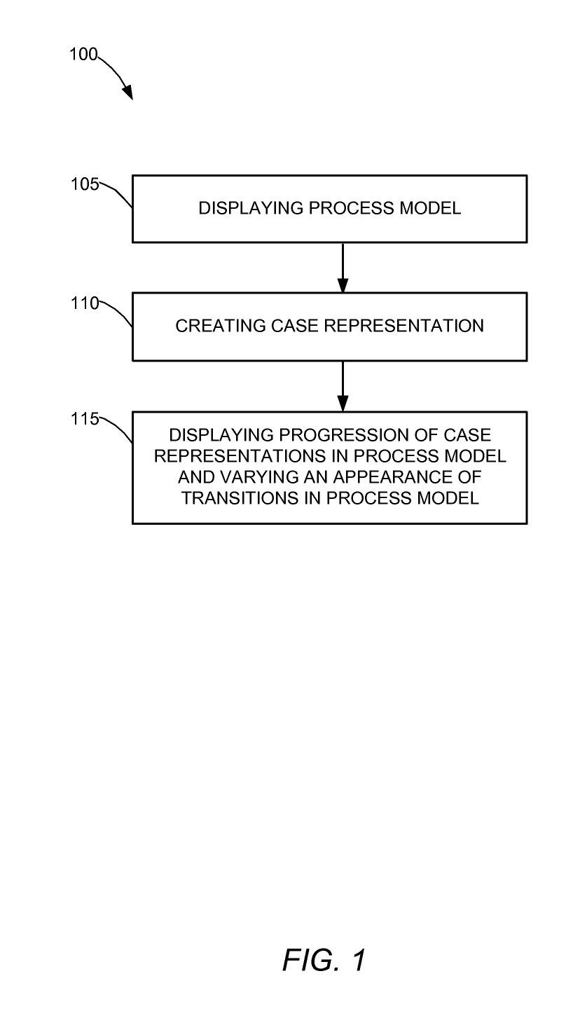

FIG. 1 illustrates one example embodiment for process model visualization. The method for process model visualization may include displaying a process model, creating a case representation for each case in the process and displaying the progression of the case representations in the process model and varying an appearance of transitions in the process model.

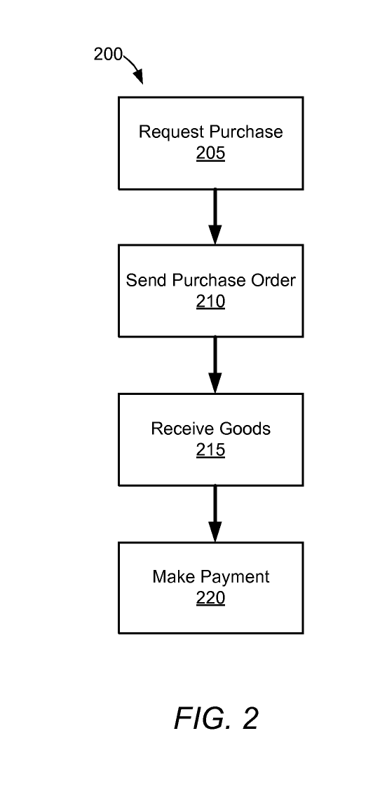

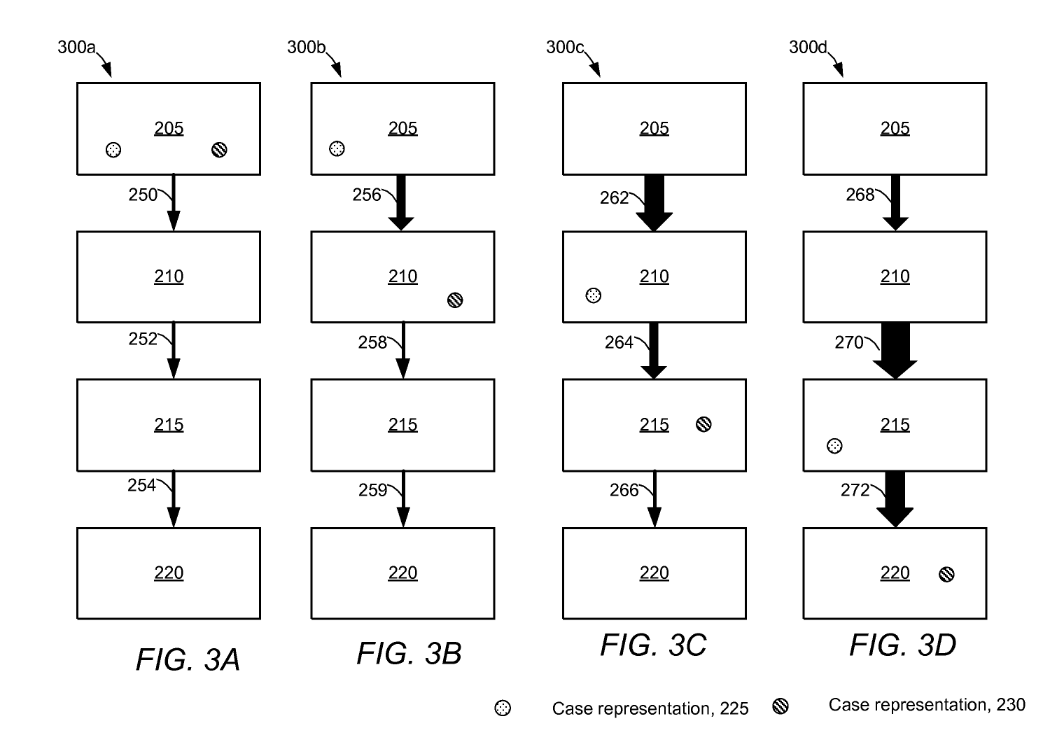

FIG. 2 shows a visualized business process model of a purchasing procedure or a purchasing process that begins in a request for a purchase and ends when a payment is made, and will be used to illustrate the method for process model visualization, as will be described in greater detail below. FIGS. 3A, 3B, 3C and 3D illustrate variations of example frames for visualizing a purchasing process model and are utilized for illustrative purposes. Process model visualization, however, is not limited to purchasing procedure process modeling. Rather, process model visualization is applicable to any workflow or process used in any business or industry.

At block 105, at least one process model may be displayed on a display system for presenting the at least one process model to a user. Examples of a display system which the process model may be displayed include, but are not limited to, a display or operator panel of image forming device. In one example embodiment, display system may be an external display device. For example, the external display device may be a personal computer, a laptop, a Personal Digital Assistant (PDA), a tablet computer and a display, such as an LCD display, integrated with a computing device.

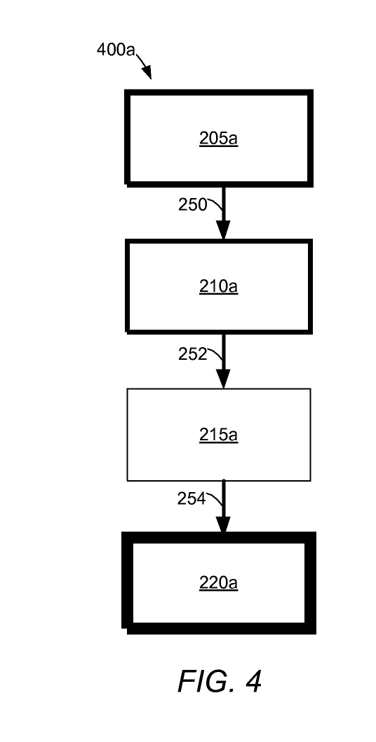

For example, as shown in FIG. 2, a process model 200 may be a visualized business process model of a purchasing procedure or a purchasing process that begins in a request for a purchase and ends when a payment is made. Process model 200 may include states 205, 210, 215 and 220 which may be indicated by state labels Request Purchase for state 205, Send Purchase Order for state 210, Receive Goods for state 215, and Make Payment for state 220. In FIGS. 3A-3D and FIG. 4, process model 200 is shown as example frames 300a-300d and 400a of a progression that will be discussed in greater detail below.

In continued reference to FIG. 1, at block 110, at least one case representation may be created. Case representations may refer to one or more visual elements that may be displayed on the display system that represent one or more cases from the process that is embodied by process model 200. Cases may refer to instances that a state or a transition in the process is performed, accessed or executed. For illustrative purposes, process model 200 may be a visualized model of a purchasing process that is generated based on data received from a user or from a set of input data. In the purchasing process, when one activity, represented in process model 200 as one of states 205, 210, 215 and 220, is executed in the purchasing process, an instance of execution of the state may be referred to as a case in process model 200. For example, when an execution of Request Purchase Process 205 occurs, this instance of execution may correspond to a case in the process model.

Case representation may be a visual representation of a case in process model 200. FIGS. 3A-3D show illustrative process model 200 as frames 300a-300d of a progression. In FIG. 3A, a case representation 225 may be found in state 205. Case representation 225 may be a visual representation of one case in the purchasing process as displayed in process 210 model 200. Another case representation 230 is shown which may correspond to another case in the purchasing process. In an alternative example embodiment, one case representation may represent two or more cases from the process.

Case representations 225 and 230 are used herein for the purpose of description and should not be regarded as limiting. As shown in FIGS. 3A-3D, case representations 225 and 230 may be in the form of bubbles or circles. In an alternative example embodiment, case representations may have a shape other than a circle, such as, for example, a square, a triangle, and a rectangle, among many others. Case representations 225 and 230 may be displayed in process model 200 as having a single color. In other alternative example embodiments, case representations 225 and 230 may have different colors that may distinguish one case from another. In yet other alternative example embodiment, case representations may be distinguished from one another with the use of different shadings, patterns, fills and other formatting properties that will be known in the art.

In continued reference to FIG. 1, at block 115, case representations 225 and 230 may be displayed in a progression from one state and transition to another in process model 200. The progression may be an animation wherein a case representation is shown as transitioning from one state or transition to another.

FIGS. 3A-3D show process model 200 in different frames, corresponding to frames 300a-300d, all of which, for illustrative purposes, visualize the movement of case representations 225 and 230 from one state or transition to another. The frames may refer to images which compose a moving picture or animation that shows movement of case representations in a process model. In an example embodiment, frames may refer to a specific time in the time period from which the cases and the case representations were retrieved. In this example embodiment, positions of the case representations may correspond to the state of the cases at a given time moment in the time period.

In an alternative example embodiment, the time that the one or more frames in the visualization correspond to may refer to a specific time, which may be one of an absolute or relative time in the process from which the cases and the case representations were retrieved. When the one or more frames refer to a time moment in the time period, cases that have not yet started or have already finished at the position in time that the frame refers to may have no representation. In another alternative example embodiment, cases that have not yet started or have finished at the position in time may be displayed as having a different representation as those of other cases that are currently being performed at the defined position in time.

Frames 300a-300d may be a sequence of images that create an illusion of movement of the case representations 225 and 230 to show progression of the case representations in process model 200 during the purchasing process. Movement of case representations from one frame to another may indicate progression of cases in a process (e.g. purchasing process) visualized in a process model for a given period of time.

Frames 300a and 300d may be key frames in the progression visualization of the case representations. Frame 300a in FIG. 3A may represent a starting point at which the visualization of case representations 225 and 230 are first displayed which may indicate the first positions of case representations 225 and 230 in the progression. Frame 300d in FIG. 3D may represent an end point at which the visualization ends which may indicate a final position of case representations 225 and 230 in process model 200 in the progression. Frames 300b and 300c may be the frames between the two key frames or key points and may show the movement of case representations 225 and 230 from their starting point in frame 300a to their end point in frame 300d.

In FIG. 3A, case representations 225 and 230 may appear in state 205. As discussed above, the appearance of case representations 225 and 230 may indicate that two cases may exist for Request Purchase state 205 or that an execution or access of Request Purchase state 205 is performed in the purchasing process visualized in frame 300a.

In FIG. 3B, case representation 230 is shown to be in Send Purchase Order state 210. Frame 300b, as discussed above, shows a frame subsequent to the frame visualized in frame 300a, which may indicate that case representation has moved from its location in Request Purchase state 205 in frame 300a to Send Purchase Order 210 in frame 300b.

In continued reference to FIG. 3B, case representation 225 is shown to be in Request Purchase state 205, which may indicate that the case corresponding to case representation 225 has stayed in the same state in two frames. This may indicate that case representation 225 has not progressed to another state in a given amount of time as represented by two frames, while case representation 230 has moved from state 205 to state 210.

In FIG. 3C, case representation 225 is located in state 210 which may indicate that case representation 225 has moved from state 205 to state 210 after two frames. Case representation 230 in FIG. 3C is now located in state 215, which indicates further movement of case representation 230 from state 210 to state 215 in the third frame.

In FIG. 3D, case representation 225 is located in state 215 while case representation 230 is located in state 220. For illustrative purposes and as aforementioned, frame 300d in FIG. 3D may be an endpoint or an end key frame of the progression visualization of case representations 225 and 230. As such, the locations of the case representations in this frame may indicate the final position of the cases that case representations 225 and 230 correspond to, for a given period of time.

The number of cases to be visualized may be determined by a user. The user may explicitly indicate the number of cases he or she wishes to visualize. In an alternative example embodiment, the user may choose a time period from the data from which the process model is modeled and the number of cases executed during the set time period may be retrieved. The time period may be automatically set or may be set by the user. For example, a user may set the time period to visualize case representations from October 2006 to February 2007 from a raw set of data. Using the configured time period, cases performed from October 2006 to February 2007 may be retrieved and visualized. The time period may determine the number of cases, and consequently, the number of case representations to be visualized.

A length of time for visualization of the progression of the case representations may be automatically set or may be set by the user. The visualization length may indicate the total amount of time to animate and show the case representations moving from one state or transition to another.

For example, a user may set a time period of one year from January 2006 to December 2007 and a number of cases are determined to have been executed during that time period. The user then sets a visualization time period for visualizing the progression of the cases to 60 seconds. In this particular example, the progression of cases executed from January 2006 to December 2007 are to be visualized in 60 seconds, which may result to a faster animation compared to visualizing cases executed from a shorter time period such as, for example, January 2006 to June 2006, in the same interval of 60 seconds. It is to be understood that the longer the time period from which a number of cases is retrieved for visualization at a given time interval, the faster the speed of the visualization is going to be. In an alternative example embodiment, if the time period from which a number of cases are retrieved for visualization is shorter, the speed of the visualization at the same given time interval may be slower compared to the visualization of the cases from the longer time period.

In some alternative example embodiments, case representations may not be displayed properly due to a fast frame rate used to animate the movement of the case representations, as in animations where cases are retrieved from a longer time period but visualized in a relatively short length, as discussed above. The progression of these case representations from one state or transition to another may be too fast such that the case representations may be at a starting state in one frame, and then at a end state in the next frame.

In continued referenced to FIG. 1, at block 115, an appearance of one or more transitions in the process model 200 may be varied. Varying the appearance of the transitions may be based on performance metrics such as, for example, the number of case representations that progress from one state to a next state at a time interval.

In an alternative example embodiment, other performance metrics that determine the variation of the appearance of the transitions may include, but may not be limited to, a number of different case types; amount of money involved in the process; a number of cases where the transition takes more or less time compared to a predetermined threshold; or at least one of an average, minimum or maximum total time that the transition took place. Other metrics that may be used to determine the arc widths of the transitions may include suppliers, types of goods involved in a transaction, personnel handling the transactions in the process, metadata that describes at least one of the states and the transitions in the process, cost involved, time-related attributes (e.g. delays), amount of labor involved in the process, company codes and other company-related information, mistakes in handling of the cases, fees and charges (e.g. billable hours), revisions or reworks, and other metrics that may be apparent to one of ordinary skill in the art.

Another performance metric may be data determined using a subset of cases from the cases represented in the process model. For example, information may be deduced using a comparison between one subset of cases against another subset of cases. This information may then be used to determine the arc widths of the transactions in the visualization.

These performance metrics may be referred herein as transaction-related data that are used to determine the arc widths for each of the transitions in the model. For example, if the specified performance metric is the amount of money involved in the process, the arc widths of each of the transaction may change in the course of the visualization, depending on the amount of money transitioning from one state to another in the process at a specified time in the process.

Varying the appearance of the transitions may include varying the width or the thickness of the transitions, based on a specified performance metric. In alternative example embodiments, varying the appearance of the transitions may include varying at least one of a color, an intensity or one or more line patterns of the transitions.

FIGS. 3A-3D show process model 200 in four example frames of a visualization of process model 200, as shown in frames 300a-300d, with transitions varying for each frame, as an illustrative example embodiment of the present disclosure. As discussed above in reference to frames 300a-300d in FIGS. 3A-3D, the frames may refer to a specific time in the time period from which the cases and the case representations were retrieved. In this example embodiment, positions of the case representations may correspond to the state of the cases at a given time moment in the time period.

In FIG. 3A, frame 300a may include transitions 250, 252 and 254 having substantially the same width. Frame 300a may correspond to a first frame in the animation of process model 200, wherein case representations may not have moved from one state to another, thus presenting transitions 250, 252 and 254 as having substantially the same width. In an alternative example embodiment, a default arc width may be assigned to a transition to indicate a transition with substantially zero volume of cases that progress from its input state to its output state. For example, transition 250 may have a default arc width signifying that there are no cases progressing from its input state 205 to its output state 210 for a time interval in the visualization.

In FIG. 3B, frame 300b shows transition 256 having a substantially wider arc width compared to transition 258 and 260. A wider arc width may show that one or more case representations have progressed from input state 205 to output state 210 through transition 256, giving transition 256a wider arc width compared to transitions 258 and 260.

In FIG. 3C, frame 300c shows transitions 262, 264 and 266, each transition having different arc widths with transition 262 having the largest arc width, transition 264 having the second largest arc width, and transition 266 having the smallest arc width. The varying arc widths of transitions 262, 264 and 266 may indicate that each of the input and output states of each of the transitions may be varied, with transition 262 having the most volume of cases progressing from its input state 205 and output state 215, transition 264 having the second highest number of cases progressing from its input state 210 and output state 215, and transition 266 having the least number of cases progressing from its input state 215 and 220.

In FIG. 3D, frame 300d shows transitions 268, 270 and 272 with transition 270 having the largest arc width, followed by transition 272 and transition 268.

A width of each of the transitions in a process model, which may appear in a frame in the animated visualization of the process, may be determined using the highest value of the performance metric such as, for example, a volume of cases for a given time interval relative to the time period as set that the frame corresponds to. For example, if a volume of cases that progress from one state to another is visualized by varying the appearance of the transitions in the process model, the width of the transitions may be based on the number of cases that move from one state to another.

The width of the transitions may be determined by identifying the values of the performance metric being visualized and assigning the values to the corresponding transition. For example, using frame 300d, the number of cases that are determined to progress from state 205 to state 210 is determined to be 200; the number of cases progressing from state 210 to state 215 is 400; and the cases progressing from state 215 to state 220 is 300.

Using these values, the volume may then be assigned to their corresponding transition. For example, in transition 268, the value 200 may be assigned using the number of cases determined to progress from state 205 to state 210. Accordingly, the values of 400 and 300 may be assigned to transitions 270 and 272, respectively.

With corresponding values assigned to each of the transitions in frame 300d, the transition having the widest width may then be determined using the highest value identified. For example, since the highest number of cases that progress from one state to another is 400 with a corresponding transition 270, transition 270 may be assigned with the widest arc width such as, for example, 10 pixels.

Using the determined arc widest arc width, the arc widths of the other transitions may be determined by scaling down the widths of the remaining arcs from the largest arc width. Scaling down the arc widths for each of the remaining transition may include adjusting the size or widths of the transitions relative to the arc width of the transition determined to have the highest value of the performance metric being visualized.

For example, transition 270, having the highest volume of cases, may have an arc width of 10 pixels. Transition 272, determined to have the second highest volume of cases, may be calculated to have an arc width of 7.5 pixels, the width having been determined by proportionally reducing the arc width based on the determined arc width of transition 270 and the volume of cases associated with transition 272. Further, transition 268, determined to have the third highest volume of cases, may be calculated to have an arc width of 5 pixels, with the width proportionally reduced based on the determined arc widths of both transitions 270 and 272, and the volume of cases associated with transition 268 relative to the number of cases for transitions 270 and 272. Other methods for determining the arc widths of the one or more transitions may be used as will be apparent to one of ordinary skill in the art.

In an alternative example embodiment, one frame in the visualization of process model 200 may contain two or more transitions having similar arc widths. This may indicate that for a particular interval in the visualization, the two or more transitions may be determined to have a substantially similar volume of cases that progress from their respective input and output states.

In another alternative example embodiment, the appearance of the states may be varied during the visualization of the progression of case representations from one state to another. The appearance of the states may be varied based on a performance metric, such as the number of case representations that is in the state for a given amount of time during the visualization. Varying the appearance may include increasing a line weight of the figure corresponding to a state in the process model. Line weight may refer to at least one of a strength, heaviness or darkness of a line or visual element that corresponds to the state.

For illustrative purposes, FIG. 4 shows frame 400a which may be an example frame in the visualization of process model 200 with states varying for each frame. In frame 400a, appearance of states may be varied based on one or more performance metrics, such as, for example, the volume of case representations occurring in the state for a given amount of time. The box in frame 400a corresponding to state 220a is shown to have a heavier line weight compared to states 205a, 210a and 215a. This may indicate that state 220a contains the most number of case representations in a frame of the visualization compared to states 205a, 210a and 215a. As discussed above in reference to the varying of the appearance of the transitions, varying the appearance of the states may be performed by determining the state with the highest volume of case representations for a given frame in the visualization, and scaling down the line weight of the remaining states based on their respective case volumes.

The progression of the case representations and the transitions may be visualized at a speed representing an amount of time for each of the case to reach a next state from a one state. The speed may be determined based on the total number of case representations that have to be visualized and the total amount of time for the visualization. For example, a process is to be visualized based on a data. A process model corresponding to the process may be generated from the data, the process model to be visualized as having 1500 case representations executed in a span of 12 months. When a user sets the 445 visualization time to 60 seconds, 1500 case representations executed in 12 months may be visualized in 60 seconds which may produce a fast visualization or animation of the progression of the case representations from one state to another. In this example, the animation may be too fast such that the progression of one or more case representations may not be properly visualized and the changes in the appearance of the states or transitions may be rapid for every frame in the animation.

While the example embodiments of this disclosure are described in connection with business process models, the animation or appearance varying techniques described herein may also be used in social network modeling.

It will be appreciated that the actions described and shown in the example flowcharts may be carried out or performed in any suitable order. It will also be appreciated that not all of the actions described in FIG. 1 need to be performed in accordance with the embodiments of the disclosure and/or additional actions may be performed in accordance with other embodiments of the disclosure.

Many modifications and other embodiments of the disclosure set forth herein will come to mind to one skilled in the art to which these disclosure pertain having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A method of visually representing a process, comprising:
creating a case representation;
representing the process as a workflow having states and transitions;
displaying a progression of the case representation from one state to a next state at a speed representing an amount of time for the case to reach the next state from the one state; and
varying an appearance of the transitions depending upon a performance metric at a time interval.

2. The method of claim 1, wherein the time interval is a time between two frames.

3. The method of claim 1, wherein the time interval is a fixed time.

4. The method of claim 3, wherein the fixed time is based upon a time period from which the visual representation of the process is based.

5. The method of claim 4, wherein the time period is determined from a raw set of data.

6. The method of claim 1, further comprising varying an appearance of at least one of the states depending upon the performance metric.

7. The method of claim 6, wherein the performance metric is a number of case representations in the at least one state at the time interval.

8. The method of claim 1, wherein the performance metric is a number of case representations progressing from the one state to the next state at the time interval.

9. A method of visually representing a process, comprising:
creating a case representation for each case in the process;
representing the process as a workflow having states and a transition;
displaying a progression of each case representation from one state to a next state at a speed representing an amount of time for the each case to reach the next state from the one state; and
varying an appearance of the transition depending upon one or more transaction-related data at a time interval.

10. The method of claim 9, wherein the transaction-related data is a number of case representations meeting a criteria and progressing from the one state to the next state at a time interval.

11. The method of claim 9, wherein the progression of the each case representation corresponds to a time period.

12. The method of claim 11, wherein the time period is set by a user.

13. A method of visually representing a process, comprising:
creating a case representation for each case in the process;
representing the process as a workflow having states and a transition;
displaying a progression of each case representation from one state to a next state at a speed representing an amount of time for the each case to reach the next state from the one state; and
displaying information relating to at least one of a number of case representations progressing from the one state to the next state and a number of case representations in at least one state at a time interval,
wherein the progression of the each case representation from the one state to the next state corresponds to a time period.

14. The method of claim 13, wherein the displayed information is presented by varying an appearance of the transition depending upon a number of case representations progressing from the one state to the next state at the time interval.

15. The method of claim 13, wherein the displayed information is presented by varying an appearance of at least one of the states depending upon the number of case representations in the at least one state at the time interval.

16. The method of claim 13, wherein the displayed information is text associated with the number of cases progressing from the one state to the next state at the time interval.

17. The method of claim 13, wherein the displayed information is text associated with the number of cases at the at least one state at the time interval.

18. The method of claim 13, wherein the displaying the progression is an animation of the progression of each case representation from the one state to the next state.

19. The method of claim 18, wherein a frame of the animation corresponds to a time moment in the time period.

20. The method of claim 18, wherein a frame of the animation displays a position of the each case representation in the state during a time moment in the time period.
